(19) United States
(12) Patent Application Publication
(10) Pub. No.: US 2015/0036312 A1
(43) Pub. Date: Feb. 5, 2015

(54) FILM FOR A DISPLAY APPARATUS AND DISPLAY APPARATUS COMPRISING THE SAME

(71) Applicant: SAMSUNG ELECTRONICS CO., LTD., Suwon-si (KR)

(72) Inventor: Ho-seong SEO, Suwon-si (KR)

(73) Assignee: SAMSUNG ELECTRONICS CO., LTD., Suwon-si (KR)

(21) Appl. No.: 14/447,931

(22) Filed: Jul. 31, 2014

(30) Foreign Application Priority Data
Jul. 31, 2013 (KR) 10-2013-0091173

(51) Int. Cl. H05K 1/02; F21V 9/14

(52) U.S. Cl. CPC H05K 1/028; F21V 9/14
USPC 362/19; 361/749; 442/286; 428/217; 428/175; 442/287; 442/290

(57) ABSTRACT

Provided are a film for a display apparatus and a display apparatus including the film. The film may include a substrate layer, a self-restoration layer disposed on the substrate layer and being configured to restore its original state after being damaged by an external impact, and a fiber network layer disposed in at least a portion of the self-restoration layer.

### CROSS-REFERENCE TO RELATED APPLICATION(S)

This application claims the benefit under 35 USC §119(a) of Korean Patent Application No. 10-2013-0091173, filed on Jul. 31, 2013, in the Korean Intellectual Property Office, the disclosure of which is incorporated herein in its entirety by reference.

### BACKGROUND

1. Field

Apparatuses and methods consistent with exemplary embodiments relate to a film for a display apparatus and a display apparatus including the film.

2. Description of Related Art

Rapid developments in information communication technologies are changing typical imaging devices into comprehensive portable computers. For example, the function of a portable terminal has gone from simple communication or text transmission to comprehensive portable computer functions, such as Internet searching, transmission and reception of digital video information, digital multimedia broadcasting (DMB), MP3 media, games, fax, email, and the like.

As a result, users of portable terminals can transmit and receive a variety of data items as well as search, acquire, and share real-time information whenever and wherever without limitations of time and space.

To improve user convenience, portable terminals are now provided with touch screens. Accordingly, users can input user commands more frequently through the touch screens of the portable terminals. However, in the process of inputting user commands through a touch screen, a portable terminal may be damaged by excessive impact, a sharp object contacting the screen, an unintended touch, and the like.

### SUMMARY

Exemplary embodiments overcome the above disadvantages and other disadvantages not described above. Also, an exemplary embodiment is not required to overcome the disadvantages described above, and an exemplary embodiment of the present inventive concept may not overcome any of the problems described above.

One or more exemplary embodiments provide an impact resistant film and a display apparatus including the film. The film may include a flexible film.

Additional aspects will be set forth in part in the description which follows and, in part, will be apparent from the description, or may be learned by practice of the presented embodiments.

According to an aspect of an exemplary embodiment, there is provided a film for a display apparatus includes a substrate layer, a self-restoration layer disposed on the substrate layer and being configured to restore its original state after being damaged by an external impact, and a fiber network layer which is disposed in at least a portion of the self-restoration layer.

The fiber network layer may include at least two fibers interconnected among a plurality of fibers.

The fiber network layer may include a plurality of fibers woven together.

The hardness of the fiber network layer may be greater than that of the self-restoration layer.

The fibers of the fiber network layer may be made of glass.

The fiber network layer may be bent at least once in a thickness direction of the film.

The fiber network layer may be disposed in the self-restoration layer.

A portion of the fiber network layer may be disposed in the self-restoration layer and another portion of the fiber network layer may be disposed in the substrate layer.

The self-restoration layer may include an acrylic resin.

At least one of nano-capsules and micro-capsules may be distributed in the self-restoration layer.

The substrate layer may include at least one from among polyethylene terephthalate (PET), a polyethylene terephthalate copolymer (co-PET), polymethyl methacrylate (PMMA), and a polymethyl methacrylate copolymer (co-PMMA).

At least one of the substrate layer, the self-restoration layer, and the fiber network layer may be transparent.

The film may be flexible.

The film may further include an adhesive layer disposed on a bottom surface of the substrate layer.

The film may be configured to be attached and detached from the display apparatus.

The substrate is configured to attach to a surface of a touch screen.

According to an aspect of another exemplary embodiment, provided is a display apparatus that includes a display panel, and a film which is disposed on top of the display panel, the film including a substrate layer, a self-restoration layer disposed on the substrate layer and being configured to restore its original state after being damaged by an external impact, and a fiber network layer which is disposed in at least a portion of the self-restoration layer.

The self-restoration layer of the film may be exposed to the outside.

The substrate layer of the film may be configured to perform a light polarization function.

The substrate layer of the film may be implemented as a substrate layer of a touch panel.

The display apparatus may be flexible.

According to an aspect of another exemplary embodiment, there is provided a cover for a surface of a touch screen, the cover including a self-restoration layer that is configured to restore itself in response to contact, a substrate supporting the self-restoration layer and being configured to attach to a surface of the touch screen, and a fiber network disposed within the self-restoration layer and comprising a material that is harder than a material of the self-restoration layer.

The fiber network may be partially included in the self-restoration layer and partially included in the substrate layer.

The touch screen may comprise two fiber networks.

A first fiber network from among the two fiber networks may be included in the self-restoration layer and a second fiber network from among the two fiber networks may be partially included in the self-restoration layer and partially included in the substrate layer.

### BRIEF DESCRIPTION OF THE DRAWINGS

The above and/or other aspects will be apparent and more readily appreciated from the following description of the embodiments, taken in conjunction with the accompanying drawings in which:

FIG. 1A is a diagram of a film for a display apparatus according to an exemplary embodiment;

FIG. 1B is a diagram of a fiber network layer in the film for a display apparatus shown in FIG. 1A;

FIGS. 2A and 2B are diagrams illustrating a process of repairing damage to a film caused by a scratch according to an exemplary embodiment;

FIGS. 3A through 3D are diagrams illustrating variations of a film for a display apparatus according to an exemplary embodiment;

FIG. 4 is a diagram of a film that is attached to the screen of a display apparatus according to an exemplary embodiment;

FIG. 5 is a diagram of a part of a display apparatus including a film according to an exemplary embodiment;

FIG. 6 is a diagram of a film that also performs a light polarization plate function according to an exemplary embodiment; and

FIG. 7 is a diagram of a part of a display apparatus that has a touch screen function according to an exemplary embodiment.

### DETAILED DESCRIPTION

Reference will now be made in detail to exemplary embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, should be understood to modify the entire list of elements and not as modifying the individual elements of the list.

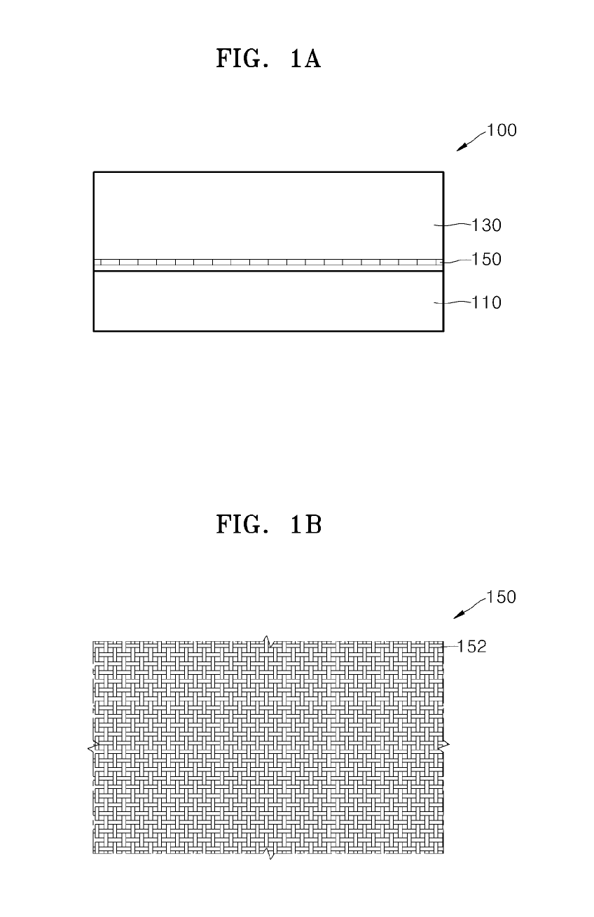

FIG. 1A is a diagram of a film 100 for a display apparatus, according to an exemplary embodiment and FIG. 1B is a diagram of a fiber network layer 150 in the film 100 for a display apparatus shown in FIG. 1A.

Referring to FIGS. 1A and 1B, the film 100 for a display apparatus includes a substrate layer 110, a self-restoration layer 130 which is provided on the substrate layer 110, and a fiber network layer 150 which is provided in at least a partial area of the substrate layer 110 and the self-restoration layer 130. The substrate layer 110, the self-restoration layer 130, and the fiber network layer 150 may be transparent and flexible. The film 100 may be attached to or otherwise provided on the outermost area of a display apparatus to protect the display apparatus. According to various aspects, as is further explained herein the self-restoration layer 130 has the ability to restore itself in response to a scratch or other damage. For example, when the film 100 is attached to or covering a screen of a display device such as a mobile phone, a smart phone, a television, a tablet, a touch screen, and the like, the film 100 may prevent the display device from being damaged. Accordingly, the film 100 may act as a protective cover for an apparatus that receives a touch input from a user.

The substrate layer 110 is transparent and may have a strong adhesive power with other layers. The substrate layer 110 may be formed of a flexible material. In order to maintain the flexible feature of the film 100 for a display apparatus, the hardness of the substrate layer 110 may be increased. For example, the substrate layer 110 may include at least one selected from the group consisting of polyethylene terephthalate (PET), polyethylene terephthalate copolymer (co-PET), polymethyl methacrylate (PMMA), polymethyl methacrylate copolymer (co-PMMA), and the like. As further described herein, the substrate layer 110 may be an element of the display apparatus that may be shared with other elements of the display apparatus.

The self-restoration layer 130 may be formed on a front surface of the substrate layer 100. The self-restoration layer 130 is a layer which has an ability to repair damage over time. For example, if a scratch damages a surface of the self-restoration layer 130, an original state or a nearly original state of the self-restoration layer 130 may be restored.

The self-restoration layer 130 may include surface-treated silica that is based on an acrylic resin and photopolymer-type acrylate, and a fluorinated compound may be added. For example, a resin composition formed with acryl-modified polyester polyols and a melamine hardener may be added to a siloxane-modified acrylic resin. As another example, the self-restoration layer 130 may be formed with a resin composition including acrylic resin, aliphatic polyester resin, silicon modified polyacrylate resin, a polydimethyl siloxane, an alcoxysilane compound, and an aliphatic isocyanate hardener. In addition, capsules of a nanometer or micrometer size may be distributed within the self-restoration layer 130. Accordingly, if an external impact occurs on the self-restoration layer 130, the capsules may be separated from each other and then return to original locations over time thereby repairing damage caused by the external impact.

In at least a portion of the substrate layer 110 and the self-restoration layer 130, the fiber network layer 150 may be provided. The fiber network layer 150 may be woven in such a manner that fibers 152 with small diameters are connected to each other regularly, or are randomly connected to each other. The fibers 152 forming the fiber network layer 150 may be formed with materials that have a hardness that is greater than a hardness of the self-restoration layer 130. For example, the fibers 152 may be glass. Generally, a material with a high hardness has poor flexibility. However, if a material with a high hardness is cut in the form of fibers, and the fibers are connected to each other, a flexibility of the fiber network layer 150 can be improved by forming fine spaces.

The substrate layer 110 and the self-restoration layer 130 may be highly flexible yet lack hardness. Therefore, the probability that damage will occur from a scratch is high. Accordingly, the fiber network layer 150, which is flexible and has a greater hardness, may be provided in at least a portion of the substrate layer 110 and the self-restoration layer 130. The fiber network layer 150 may reduce the influence of an external impact on a layer provided below the self-restoration layer 130. With a greater hardness and flexibility, the fiber network layer 150 may be applied to a flexible display apparatus.

To generate the film 100 for a display apparatus, the substrate layer 110 may be formed and then, the fiber network layer 150 may be deposited on the substrate layer 110. Then, the self-restoration layer 130 may be deposited on the fiber network layer 150. As fine spaces exist in the fiber network layer 150, the self-restoration material of the self-restoration layer 130 may fill the space between the fiber network layer 150 and the substrate layer 110 by filling the existing fine spaces.

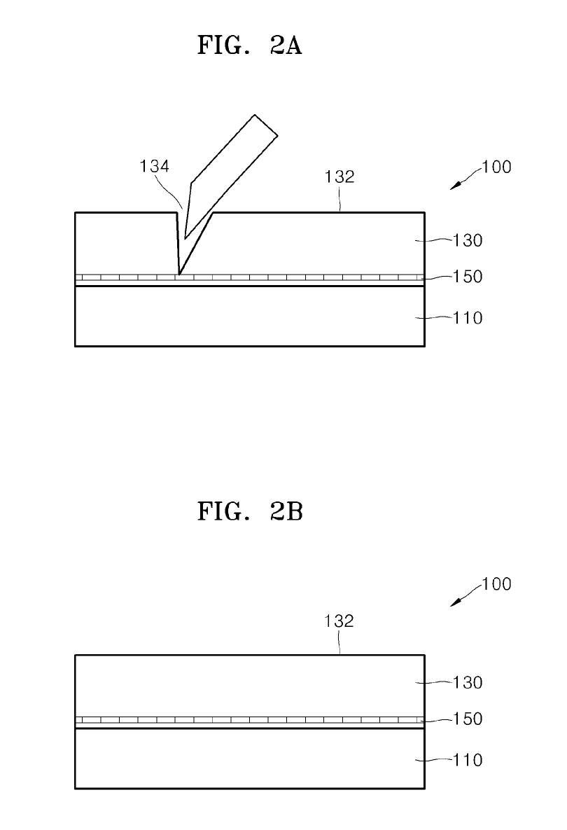

FIGS. 2A and 2B are diagrams illustrating a process of repairing damage caused by a scratch, according to an exemplary embodiment.

As shown in FIG. 2A, an external impact occurs on an exposed surface 132 of the self-restoration layer 130. In response, the material or capsules in the self-restoration layer 130 are separated from an area 134 where the impact occurs, and thus a scratch occurs. The external impact may damage the self-restoration layer 130 but does not damage the fiber network layer 150 which has a greater hardness. Accordingly, a layer provided below the fiber network layer 150 is not damaged by the impact. After the damage occurs, the material or capsules separated from the damaged area return to original positions and thus the damaged area on the exposed surface 132 of the self-restoration layer 130 may be restored to its original state as shown in FIG. 2B.

Because the fiber network layer 150 is provided on the self-restoration layer 130, external impact to other layers besides the self-restoration 130 can be prevented.

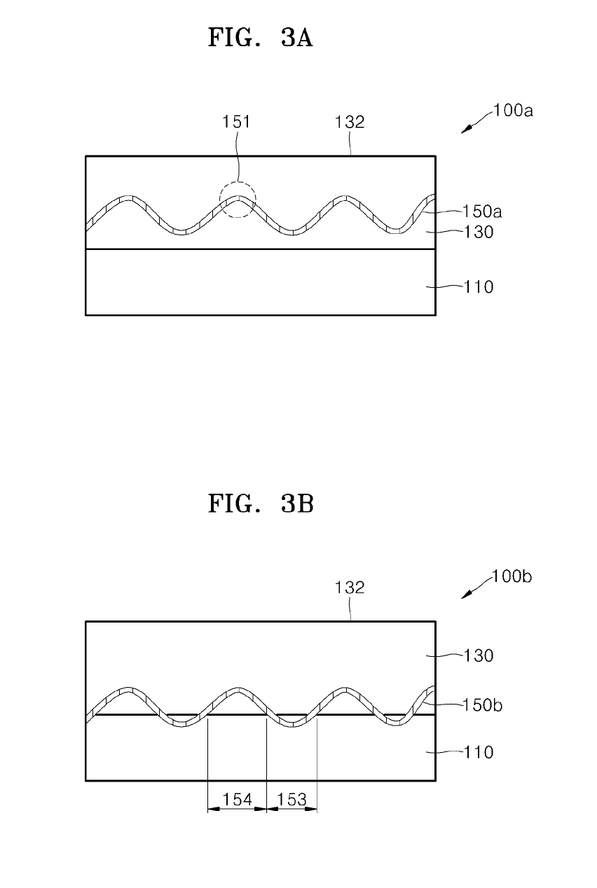

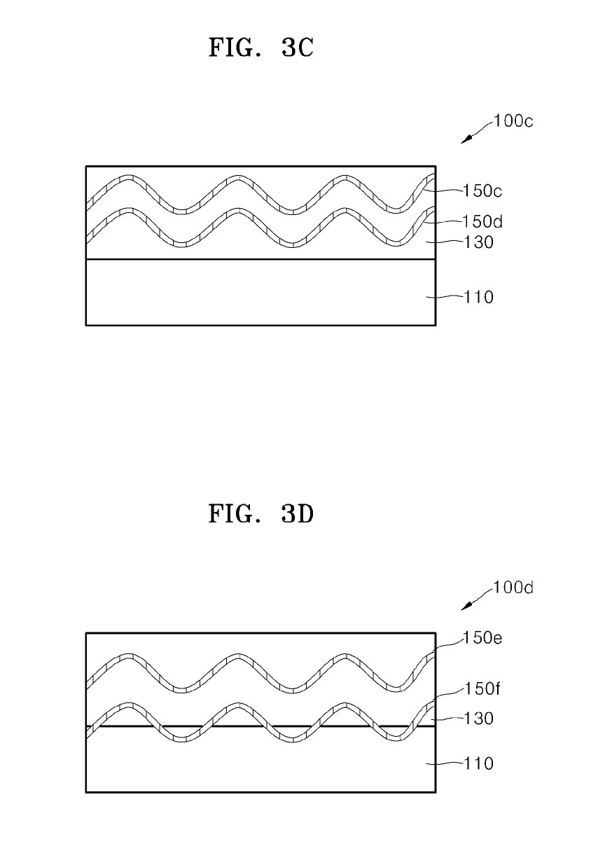

FIGS. 3A through 3D illustrate variations of a film 100a for a display apparatus, according to an exemplary embodiment.

As shown in FIG. 3A, a fiber network layer 150a includes at least one bent area 151. The bent area 151 is bent in a thickness direction of the film 100a for a display apparatus. Accordingly, the flexible feature of the fiber network layer 150a itself may be improved, and thus, the flexible feature of the entire film 100a for a display apparatus can also be improved.

In the example of FIG. 3B, a part 154 of the fiber network layer 150b is provided in the self-restoration layer 130 and the other part 153 of the fiber network layer 150 is provided in the substrate layer 110. Because the part 154 of the fiber network layer is provided in the substrate layer 110, even if an area of the substrate layer 110 is damaged by an external impact, the damaged area may be limited, and the self-restoration layer 130 may also repair the damaged area of the substrate layer 110.

In the examples of FIGS. 3C and 3D, films 100c and 100d for a display apparatus include a plurality of fiber network layers 150c through 150f, respectively. The fiber network layers 150c through 150f may be formed by connecting fibers together, and fine spaces may occur between fibers. To reduce damage by external impact, the plurality of fiber network layers 150c through 150f may be provided on a layer below the self-restoration layer 130 through the fine spaces. For example, as shown in FIG. 3C, the plurality of fiber network layers 150c and 150d are provided sequentially in the thickness direction of the self-restoration layer 130. Also, as shown in FIG. 3D, at least one fiber network layer 150e is provided in the self-restoration layer 130 and at least one other fiber network layer 150f is provided in the self-restoration layer 130 and the substrate layer 110.

The film for a display apparatus described above may be used as a film to protect a screen of a display apparatus. For example, the display apparatus may include an organic light-emitting display device (OLED), a plasma display panel (PDP), a flat cathode ray tube (FCRT), a vacuum fluorescent display panel (VFD), a light-emitting diode panel (LED), a liquid crystal display panel (LCD), and the like.

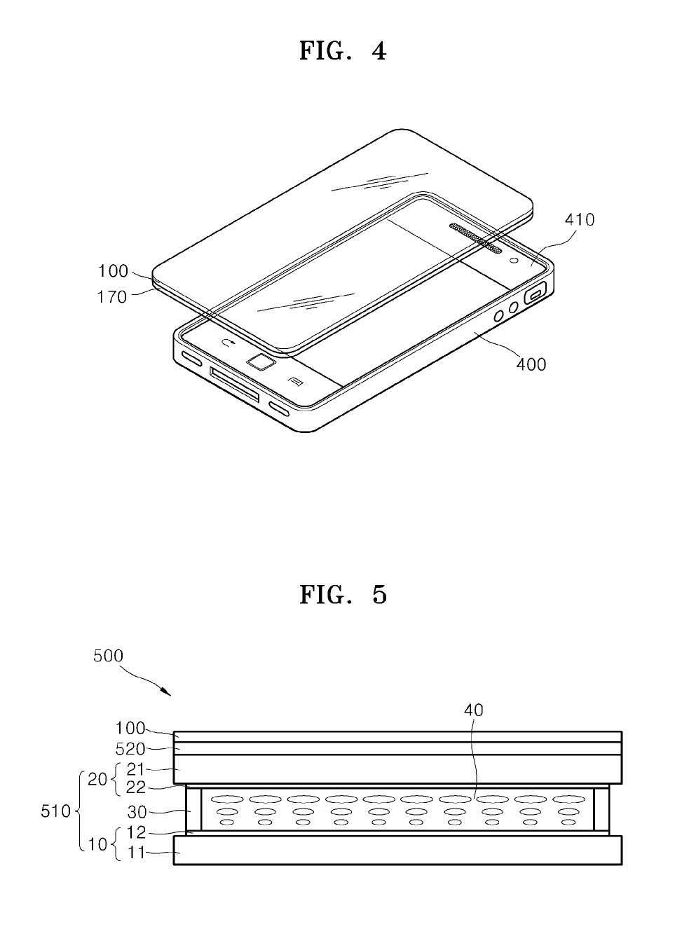

FIG. 4 illustrates a film 100 that is attached to a screen of a display apparatus 400, according to an exemplary embodiment. As shown in FIG. 4, an adhesive layer 170 may be provided on a bottom surface of a substrate layer of the film 100. Accordingly, the film 100 may be attached to or detached from a front surface 410 of the display apparatus 400 by the adhesive layer 170.

As another example, the film 100 described above may be implemented as an element integrated into a display apparatus. FIG. 5 shows a part of a display apparatus 500 including a film according to an exemplary embodiment. The display apparatus 500 shown in FIG. 5 is a liquid crystal display apparatus, but this is for convenience of explanation and it should be appreciated that the film can be applied to any type of display apparatus such as an OLED display apparatus.

As shown in FIG. 5, the display apparatus 500 includes a display panel 510, a light polarization panel 520, and a film 100. Though the display apparatus 500 also includes other elements including a driving circuit and a backlight unit, a further description thereof is omitted here for convenience of explanation.

The display panel 510 receives light from the backlight unit (not shown) and in response to a driving signal from the driving circuit (not shown), displays an image. In this example, the display panel 510 includes an array substrate 10, a color filter substrate 20, a liquid crystal layer 40 provided between the array substrate 10 and the color filter substrate 20, and a sealant 30.

The array substrate 10 is may be generated by forming a pixel array layer 12, in which a plurality of pixels are arranged in a matrix, on a first base substrate 11. Though not shown in drawings, the pixels may be defined by gate lines and data lines crossing each other in an insulated manner and may be formed with thin film transistors and pixel electrodes which electrically connect to the thin film transistors. A thin film transistor may switch a voltage to be applied to a pixel electrode. A data line may apply a pixel voltage to a thin film transistor and a gate line may apply a gate voltage to a corresponding thin film transistor. Accordingly, each pixel may apply a pixel voltage to a pixel electrode in response to a gate voltage.

The color filter substrate 20 is combined to the array substrate 10 and faces the array substrate 10. The color filter substrate 20 may be formed by forming a color array layer 22 on a second base substrate 21. The color array layer 22 may include a color filter layer, a black matrix, and a common electrode. The color filter layer is formed with a plurality of color pixels corresponding to the plurality of pixels, respectively, and the black matrix may be formed on a position corresponding to the gate lines and the data lines. The common electrode may be formed on top of the plurality of color pixels and the black matrix and facing the pixel electrodes. A common voltage, that is, a reference voltage, may be applied to the common electrode. Accordingly, depending on the potential difference between the pixel voltage and the common voltage, the transmittance of the liquid crystal layer 40 is controlled and an image is displayed on the display panel 510.

The liquid crystal layer 40 may be inserted between the array substrate 10 and the color filter substrate 20, for example, by a load insertion method or a vacuum insertion method. In the liquid crystal that forms the liquid crystal layer 40, the arrangement direction changes according to a potential difference between the pixel voltage and the common voltage, and the transmittance of light provided from a backlight unit changes according to the arrangement direction.

The sealant 30 is provided between the array substrate 10 and the color filter substrate 20 and combines the array substrate 10 and the color filter substrate 20. Also, the sealant 30 seals the liquid crystal layer 40 to prevent leaking.

The light polarization panel 520 is combined on the display panel 510 and polarizes light that is provided to the display panel 510. The light polarization panel 520 may be formed in a multilayer structure, including a support layer, an anti-static (AS) layer, and a polarizing layer. The support layer may be used to maintain durability, mechanical strength, and heat resistance, and the AS layer may prevent static electricity occurring in the light polarization panel 520 from flowing into the inside of the display panel 510.

The film 100 is attached to a surface of the light polarization panel 520 and prevents damage to the display apparatus 500. For example, the film 100 may be the film described in the above examples.

The film 100 may be an independent element of the display apparatus 500 and may also be integrated with the display apparatus 500.

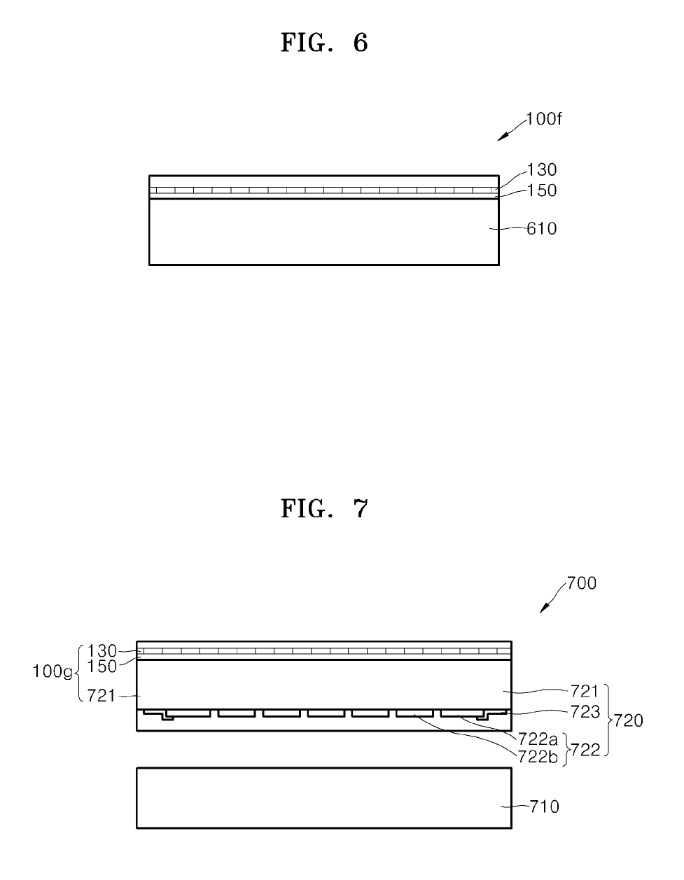

FIG. 6 is a diagram of a film 100f which also performs a light polarization plate function according to an exemplary embodiment. Referring to FIG. 6, the film 100f includes a light polarization panel 610, a self-restoration layer 130 which is provided on the light polarization panel 610, and a fiber network layer 150 which is provided in the self-restoration layer 130.

The light polarization panel 610 may include at least one layer which polarizes light provided from a display panel of a display apparatus, and which reduces the reflectance of external light. Also, the light polarization panel 610 performs the function of a substrate layer. The self-restoration layer 130 and the fiber network layer 150 are the same as those explained above and therefore the additional explanation thereof is omitted.

FIG. 7 illustrates a display apparatus 700 having a touch screen function according to an exemplary embodiment. The display apparatus 700 shown in FIG. 7 includes a display panel 710 which displays an image and a touch panel 720 which is provided above the display panel 710 and receives a touch input.

For example, the display panel 710 may include the light polarization panel 520 as well as the display panel 510 shown in FIG. 5. However, when the display panel 710 does not have a light polarization panel, such as an OLED display panel, the light polarization panel may not be included.

Referring to FIG. 7, the touch panel 720 includes a substrate layer 721, a plurality of conductive sensing cells 722 formed on a bottom of the substrate layer 721, and location detection lines 723 which connect the conductive sensing cells 722 to an external driving circuit.

The conductive sensing cells 722 may be formed on a touch activated area on one surface of the substrate layer 721 using a transparent electrode material such as Indium-Tin-Oxide (ITO). The conductive sensing cells 722 include first sensing cells 722a connected in a first direction and second sensing cells 722b connected in a second direction which is different from the first direction.

The first and second sensing cells 722a and 722b may be provided on an identical layer connected along the first and second directions, respectively, by first connection patterns (not shown) and second connection patterns (not shown). The connection patterns may be insulated from each other with insulation films provided between the connection patterns, or may be provided as different layers with an insulation film provided between the layers.

In response to a contacting object such as a human hand or a stylus pen touching the touch panel, a change in the capacitance according to a contact location is transferred from the conductive sensing cells 722 to the driving circuit (not shown) through the location detection lines 723.

On top of the substrate layer 721 is formed a self-restoration layer 130 which includes a fiber-network layer 150. The substrate layer 721 may be formed with the same materials as those of the substrate layer 110 of the film for a display apparatus described above. Accordingly, the substrate layer 721 may perform a role of supporting the self-restoration layer 130 and the fiber network layer 150 as well as a role for supporting the conductive sensing cells and the location detection lines. That is, a film 100g for a display apparatus and the touch panel 720 may share the substrate layer 721.

According to various aspects, the film for a display apparatus includes a self-restoration layer and a fiber network layer. In response to an external impact such as a scratch, a damaged area can be repaired and the state of the film can be restored. Accordingly, the film may protect the display apparatus. Also, the film has a flexible feature and is capable of protecting a flexible display apparatus.

While one or more exemplary embodiments have been described with reference to the figures, it will be understood by those of ordinary skill in the art that various changes in form and details may be made therein without departing from the spirit and scope of the present description as defined by the following claims.

It should be understood that the exemplary embodiments described herein should be considered in a descriptive sense only and not for purposes of limitation. Descriptions of features or aspects within each embodiment should typically be considered as available for other similar features or aspects in other embodiments. The examples herein may be embodied in many different forms with a variety of modifications, and a few embodiments are illustrated in drawings and explained in detail. However, this should not be construed as being limited to the embodiments set forth herein, and rather, it should be understood that changes may be made in these exemplary embodiments without departing from the principles and spirit of the invention, the scope of which is defined in the claims and their equivalents.

What is claimed is:

1. A film for a display apparatus, the film comprising:
a substrate layer;
a self-restoration layer disposed on the substrate layer and being configured to restore its original state after being damaged by an external impact; and
a fiber network layer which is disposed in at least a portion of the self-restoration layer.

2. The film of claim 1, wherein the fiber network layer comprises at least two fibers interconnected among a plurality of fibers.

3. The film of claim 1, wherein the fiber network layer comprises a plurality of fibers woven together.

4. The film of claim 1, wherein a hardness of the fiber network layer is greater than a hardness of the self-restoration layer.

5. The film of claim 1, wherein fibers of the fiber network layer comprise glass.

6. The film of claim 1, wherein the fiber network layer is bent at least once in a thickness direction of the film.

7. The film of claim 1, wherein the fiber network layer is disposed in the self-restoration layer.

8. The film of claim 1, wherein a portion of the fiber network layer is disposed in the self-restoration layer and another portion of the fiber network layer is disposed in the substrate layer.

9. The film of claim 1, wherein the self-restoration layer comprises acrylic resin.

10. The film of claim 1, wherein at least one of nano-capsules and micro-capsules are distributed in the self-restoration layer.

11. The film of claim 1, wherein the substrate layer comprises at least one selected from among a group consisting of polyethylene terephthalate (PET), a polyethylene terephthalate copolymer (co-PET), polymethyl methacrylate (PMMA), and a polymethyl methacrylate copolymer (co-PMMA).

12. The film of claim 1, wherein at least one of the substrate layer, the self-restoration layer, and the fiber network layer is transparent.

13. The film of claim 1, wherein the film is flexible.

14. The film of claim 1, further comprising an adhesive layer disposed on a bottom surface of the substrate layer.

15. The film of claim 1, wherein the film is configured to be attached and detached from the display apparatus.

16. The film of claim 1, wherein the substrate is configured to attach to a surface of a touch screen.

17. A display apparatus comprising:
a display panel; and
a film which is disposed on top of the display panel, the film comprising:
a substrate layer;
a self-restoration layer disposed on the substrate layer and being configured to restore its original state after being damaged by an external impact; and
a fiber network layer which is disposed in at least a portion of the self-restoration layer.

18. The display apparatus of claim 17, wherein the self-restoration layer of the film is exposed to the outside.

19. The display apparatus of claim 17, wherein the substrate layer of the film is configured to perform a light polarization function.

20. The display apparatus of claim 17, wherein the substrate layer of the film is shared as a substrate layer of a touch panel.
